(19) United States
(12) Patent Application Publication
(10) Pub. No.: US 2019/0368655 A1
(43) Pub. Date: Dec. 5, 2019

(54) DEVICE MOUNT

(71) Applicant: Foto Electric Supply Co., Inc., Brooklyn, NY (US)

(72) Inventor: David Goldstein, Englewood, NJ (US)

(73) Assignee: Foto Electric Supply Co., Inc., Brooklyn, NY (US)

(21) Appl. No.: 15/994,695

(22) Filed: May 31, 2018

(51) Int. Cl. F16M 13/02; F16M 11/14

(52) U.S. Cl. CPC F16M 13/022; H05K 5/0204; F16M 11/14

(57) ABSTRACT

A device mount for personal electronic devices provides flexible mounting with multiple adjustments and a wide range of viewing angle capabilities. The device mount includes an attachment portion connected to an angle adjustment unit coupled to a mounting portion. The attachment portion may be secured onto various structures, such as, for example, an airplane seat-back tray table. The mounting portion, as a result of the angle adjustment unit interconnections to the attachment portion, may be adjusted pivotally and rotationally throughout a wide range of viewing angles to optimize viewing.

### TECHNICAL FIELD

The present application relates generally to mobile device accessories. More particularly, to an assembly that mounts portable electronic devices to various surfaces.

### BACKGROUND OF THE DISCLOSURE

Numerous devices are known that are used to mount personal electronic devices (e.g. smartphones, tablets, and other communication devices) using manual or magnetic connectors. However, the existing devices have limited attachment and viewing angles.

Some mounts for electronic devices use cradles that may include clips or bottom and side supports, so that the personal electronic device may be propped or clamped or otherwise held to the mount by some combination of support arms or legs. Other products are bulky or complex, not allowing for portability and quick set-up.

Mounts such as those described above have disadvantages. For example, a mount that hooks or fastens onto the latch of a tray table does not allow for continuously secure attachment such as during cornering, acceleration, or deceleration of a vehicle in which the mount is used, or such as when an airplane experiences turbulence where the plane may bounce or lurch. Additionally, existing mounting devices do not allow for adjustable attachment to different structures. Most are made to attach to a specific device or structure limiting versatility. Most do not allow for use with an airplane tray table in its locked or open position.

### SUMMARY OF THE DISCLOSURE

The present disclosure provides a device mount for personal electronic devices that provides flexible mounting with multiple adjustments and a wide range of viewing angle capabilities. The device mount according to the disclosure includes an attachment portion connected to an angle adjustment unit coupled to a mounting portion. The attachment portion may be secured onto various structures, such as, for example, an airplane seat-back tray table. The mounting portion, as a result of the angle adjustment unit interconnections to the attachment portion, may be adjusted pivotally and rotationally throughout a wide range of viewing angles to optimize viewing.

The attachment portion is configured to attach the device mount to a structure. The attachment portion includes a front support wall and a rear support wall substantially parallel to one another. The front support wall may include a perpendicular extension with a rotation attachment. The rear support wall of the attachment portion is connected to the front support wall by a spring structure that is in tension to rigidly grasp a structure that may be disposed between the front and rear support walls. The rotation attachment of the attachment portion is configured to attach the angle adjustment unit so it can rotate and be fixed through a range of angles relative to the perpendicular extension.

The angle adjustment unit connects to the rotation attachment of the attachment portion in a t-hinge configuration. A pin connects a rotation engagement portion of the angle adjustment unit to the rotation attachment allowing the angle adjustment unit to pivot relative to the perpendicular extension. A ball-joint, at an end of the angle adjustment unit distal to the rotation engagement portion attaches the angle adjustment unit to the mounting portion.

The mounting portion is configured to mount to mobile devices and includes a ball-joint socket and a mounting surface. The ball-joint socket is configured to receive the ball-joint of the angle adjustment unit, allowing the mounting portion to pivot and swivel angularly relative to the angle adjustment unit. The mounting surface may be magnetic to allow simple and versatile attachment and removal of the mobile device.

In a further embodiment, the mounting portion may also be configured to include a magnetic surface plate that magnetically connects/disconnects with a removable mounting portion. The removable mounting portion, detached from the mounting portion, may be attached to a universal air vent clip. The universal air vent clip may have a clip magnetic surface to allow for simple and versatile attachment of a mobile device.

Other aspects of the present disclosure may be combined with one or more of the preceding aspects.

### BRIEF DESCRIPTION OF THE DRAWINGS

For the purpose of facilitating an understanding of the subject matter sought to be protected, there are illustrated in the accompanying drawings embodiments thereof, from an inspection of which, when considered in connection with the following description, the subject matter sought to be protected, its construction and operation, and many of its advantages should be readily understood and appreciated.

FIG. 1 is an exploded view of a device mounting apparatus according to an embodiment of the present disclosure.

FIG. 2 is a perspective view of the device mounting apparatus of FIG. 1 according to an embodiment of the present disclosure.

FIG. 3 is a back view of the device mounting apparatus of FIG. 1 according to an embodiment of the present disclosure.

FIG. 4A is a plan view of the side the device mounting apparatus of FIG. 1, partially in section showing the spring structure, according to an embodiment of the present disclosure.

FIG. 4B is a top-down plan view, partially in section showing the spring structure, of the device mounting apparatus of FIG. 1 according to an embodiment of the present disclosure.

FIG. 5 is a side view, partially in section showing the spring structure, of the device mounting apparatus of FIG. 1 attached to a structure such as a passenger seat-back tray table.

FIG. 6A is a side view of the device mounting apparatus of FIG. 1 with a removable mounting portion.

FIG. 6B is a side view of the removable mounting portion of FIG. 6A attached to a universal air vent clip.

### DETAILED DESCRIPTION

Various embodiments will be described in detail referring to the drawings, by way of example only and are not to be construed as limiting. For example, while some embodiments may be described as comprising a plurality of features or elements, this is not to be construed as indicating that all these features or elements are necessary for an implementation. Instead, in other implementations or embodiments, some of the features or elements described may be omitted and/or may be replaced by alternative features or elements. Furthermore, in addition to the features explicitly described and shown in the drawings, additional features or elements may be provided without departing from the scope of the present application.

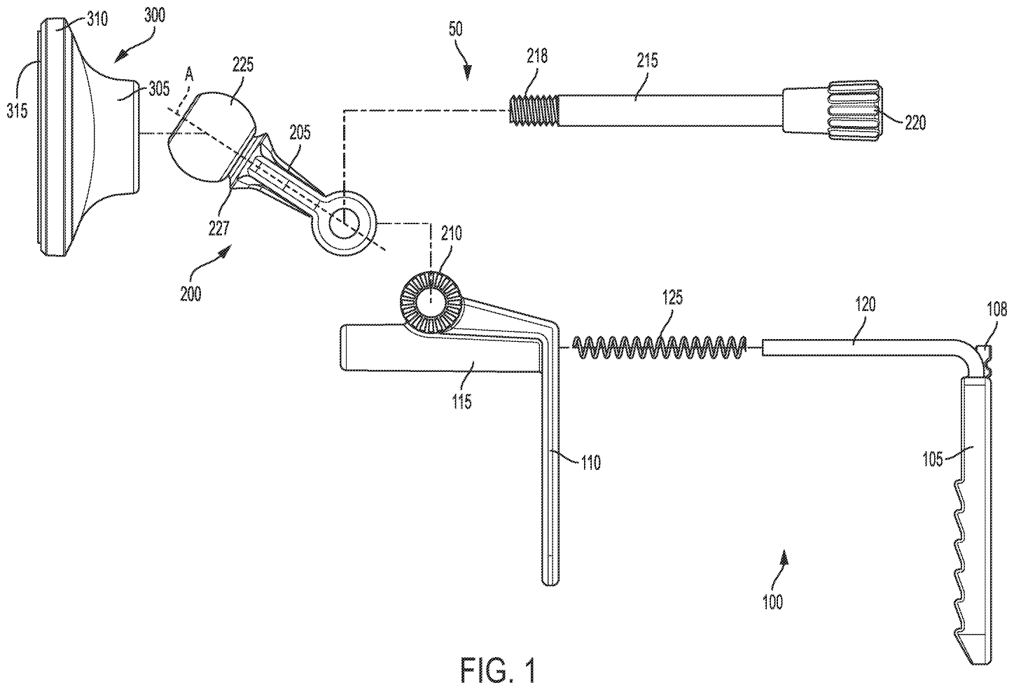

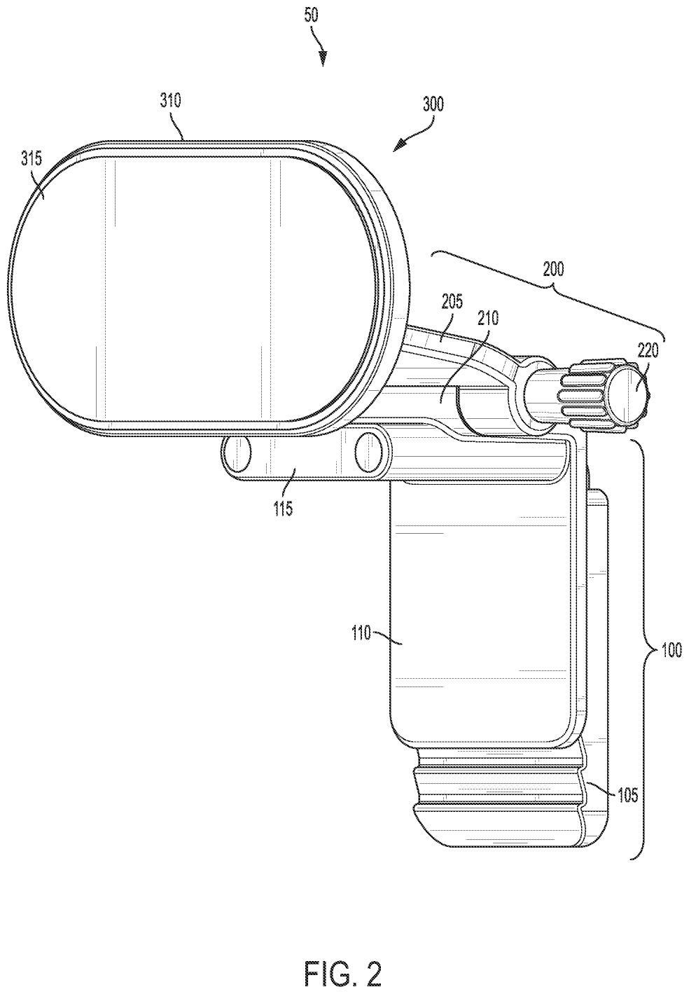

A device mount according to the disclosure attaches a mobile electronic device to a structure, such as an airplane seat-back tray table. As illustrated in FIGS. 1-4B, a device mount 50 according to the disclosure generally comprises an attachment portion 100, an angle adjustment unit 200, and a device mounting portion 300. The attachment portion 100 attaches to the structure, e.g., a tray table, or other appropriate attachment surface or structure that can be engaged by the attachment portion. The attachment portion 100 connects, via a pivot or t-hinge configuration, to an angle adjustment unit 200 allowing the angle adjustment unit 200 to be rotated or adjusted through a range of angles. The angle adjustment unit 200 is, in turn, connected to a mounting portion 300 by a ball-joint connection between a ball-joint 225 on the angle adjustment unit and a socket 305 on the mounting portion 300, allowing the device mounting portion 300 to swivel in 360 degrees.

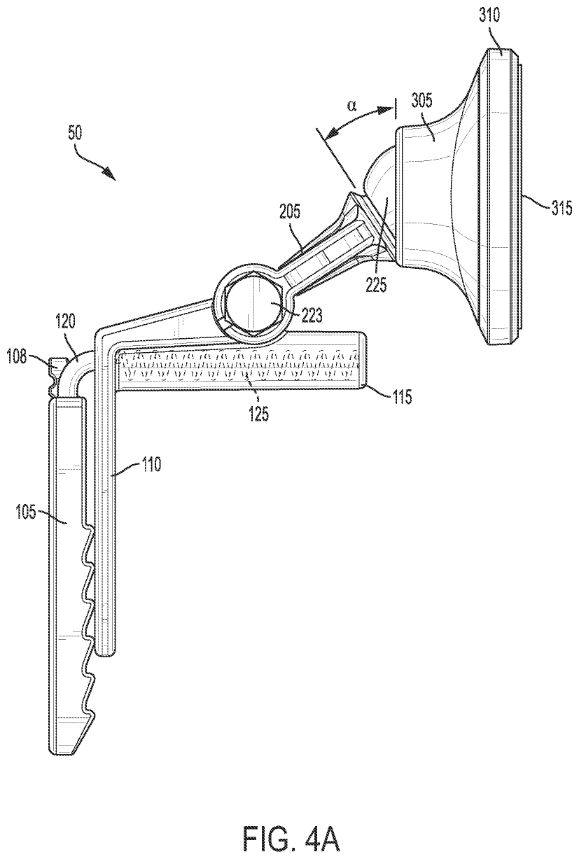

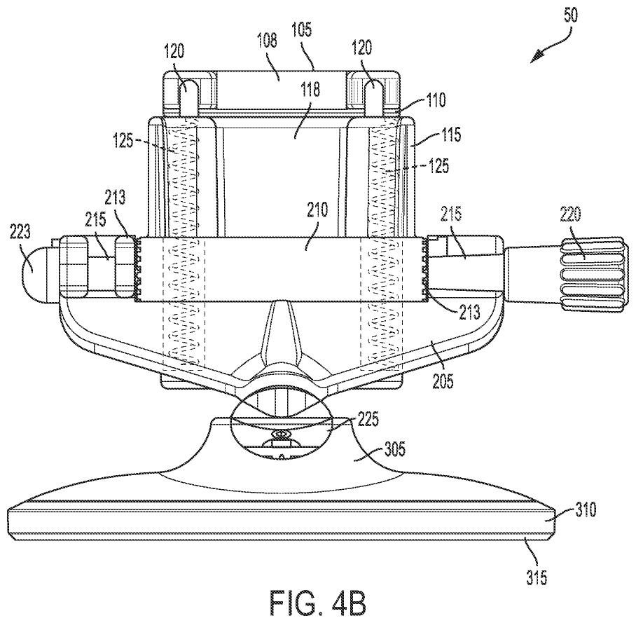

As seen in the exploded view of FIG. 1, the attachment portion 100 includes a front support wall 110 and a rear support wall 105 substantially parallel to one another. The front support wall 110 may include a perpendicular extension 115. The rear support wall 105 of the attachment portion 100 may be connected to the front support wall 110 by metal connectors 120 and a spring structure 125 (best seen in FIGS. 1 and 4A). The spring structure in this embodiment is a tension/extension spring structure that maintains the rear support wall 105 and front support wall 110 in tension against one another so that a structure (for example, an airplane tray table) can be maintained/grasped therebetween, holding the mounting device in place. A rotation attachment 210 is disposed on the perpendicular extension 115 of the front support wall 110 of the attachment portion 100. The rotation attachment 210 has a void 212 extending therethrough for receipt of a pin 220 connecting the angle adjustment unit 200 to the attachment portion 100 as described hereinafter.

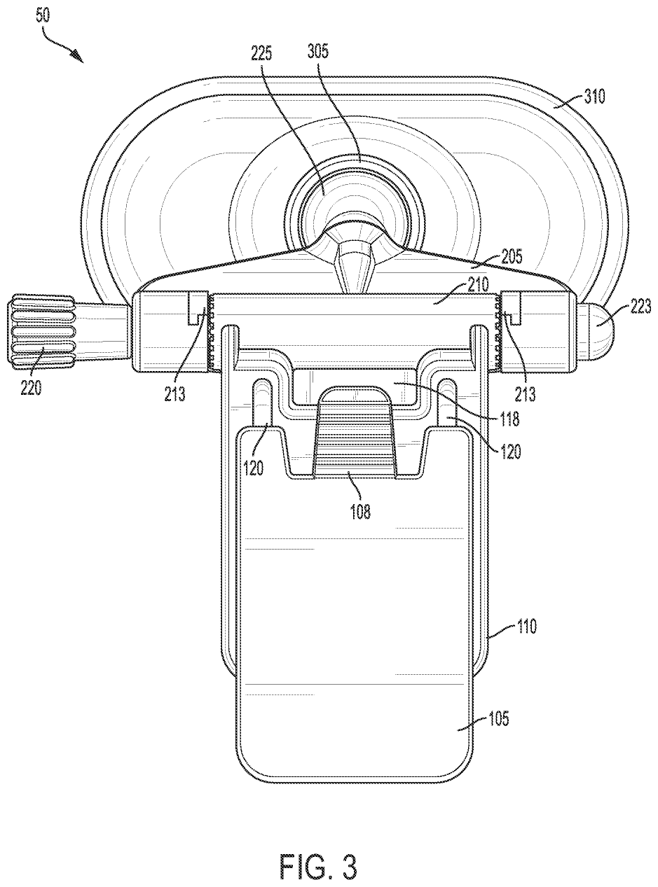

Referring still to FIG. 1, the angle adjustment unit 200 has a rotation engagement portion 205 configured to mate with the rotation attachment 210 of the attachment portion 100 resulting in the t-hinge configuration. A pin may be used to fasten the rotation engagement portion 205 of the angle adjustment unit 200 mated to the rotation attachment 210 of the attachment portion 100 allowing the angle adjustment unit to pivot in a range of approximately 0 to 180 degrees relative to the perpendicular extension 115 of the front support wall 110 of the attachment portion 100. The pin 215 may include a knob 220 at one end and screw threads 218 at the opposite end. The pin 215 inserted in the mated rotation engagement portion 205 and rotation attachment 210 may be held in place by a screw cap 223 (FIG. 3) engaging the screw threads 218 of pin 215. Rotation attachment 210 and/or rotation engagement portion 205 may include detents in order to hold the angle adjustment unit 200 in place relative to the attachment portion 100 when the screw cap 223 is tightened on the threads 218 engaging the pin 215 in place.

As illustrated in the embodiment of FIG. 3, or one or more removable bushings may be disposed between these components with detents 213 on the inner surface engaging the rotation attachment 210. The rotation attachment 210 may include detents that engage with the bushings with detents 213 allowing detent engagement to preclude rotation or pivoting of the angle adjustment unit 200 when the knob 220 is tight. By tightening the knob 220 to lock the detents, the angle adjustment unit 200 may be fixed in a position mated to the rotation attachment 210 of the attachment portion 100 at an optimized viewing angular orientation in the range of approximately 0 to 180 degrees relative to the perpendicular extension 115 of the front support wall 110 of the attachment portion 100. Knob 220 may be turned to loosen or unlock the engaged detents that lock the angle adjustment unit 200 in position relative to the attachment portion 100, allowing the angle adjustment unit 200 the ability to be pivoted to a new angular position where it can be fixed in that position by again turning/tightening the knob 220 to tightly engage the screw threads 218 of pin 215 with screw cap 223.

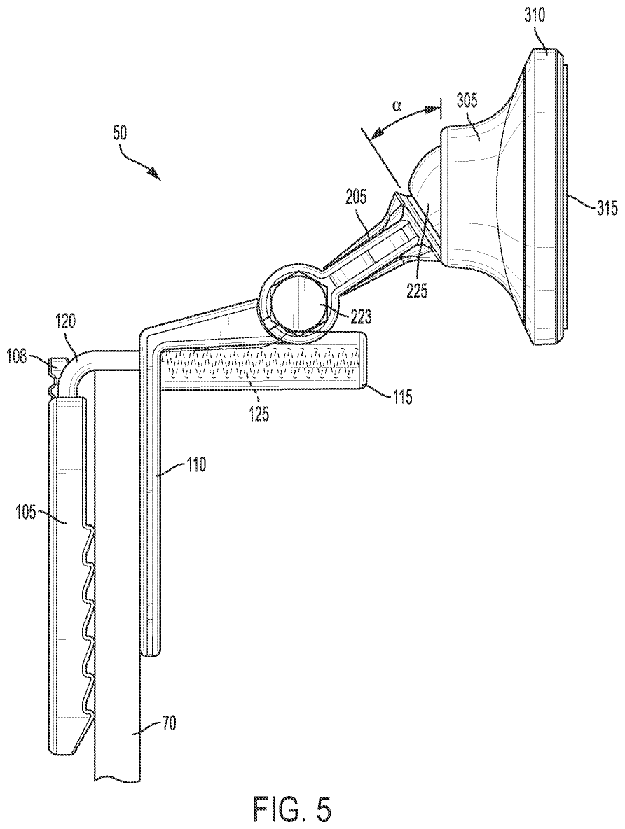

As seen in FIG. 1, at an end of the angle adjustment unit 200 distal to the rotation engagement portion 205, the angle adjustment unit 200 has a ball-joint 225. The center of the ball-joint defines a central axis, A (FIG. 1), of the angle adjustment unit 200. A stop-surface 227 is located at the base of the ball-joint 225. The ball-joint attaches the angle adjustment unit to the mounting portion 300. A ball-joint socket 305 of the mounting portion 300 is configured to receive the ball-joint 225 of the angle adjustment unit 200. The ball-joint connection allows the mobile device mounting portion 300 to swivel 360 degrees around the ball-joint 225, relative to the angle adjustment unit 200. At any angle within the 360 degree swivel, the ball joint connection also allows the mounting portion 300 to tilt in a range of acute angles, from about zero degrees (no tilt of the mounting portion 300, with the central axis A of the angle adjustment unit forming a substantially orthogonal axis relative to the center of the mounting portion 300) to approximately 45 degrees, between the substantially orthogonal axis and the stop-surface 227 (best seen as α in FIG. 4A and 5).

The mobile device mounting portion 300 may include a mounting surface 310. The mounting surface 310 may be made of different materials, for example it may be metallic. In another embodiment, it may include a first magnetic surface plate 315, allowing for use with a variety of mobile devices. The mounting surface provides an interface between a mobile device and the device mount 50. Alternatively, the mounting surface may be any of various types of surfaces that will hold or engage with a surface on a mobile device, such as hook and loop, tack surface, magnetic interfaces, suction, adhesive, or the like. With a device installed, in operation the swivel and tilt of the ball joint connection between the mounting portion 300 and the angle adjustment unit 200, along with the pivot of the rotation engagement portion 205 of the angle adjustment unit 200 mated to the rotation attachment 210 of the attachment portion 100, provides for positioning the attached mobile device for optimized viewing.

Referring specifically to FIG. 3, a rear view of the device mount 50 is shown. Rear support wall 105 may be narrower and longer than front support wall 110 to provide support and stability when attached/mounting onto a structure. The rear support wall 105 may have a tongue extension 108 existing between metal connectors 120 made of a rigid or flexible material and may include a grooved surface to aid in grip and separation of the rear support wall 105 and front support wall 110 for mounting. A recess 118 may be located between the spring structures 125. The tongue extension 108 and the recess 118 aid in allowing the rear support wall 105 and the front support wall 110 to be separated while attaching or detaching the device mount 50 with a structure or surface (such as a seat-back mounted tray table).

The rear support wall 105 may have grooved ridges on the surface nearest to and facing the front support wall 110 as seen in FIGS. 1, 2, 4A and 6A, to help secure the attachment portion 100 to a surface and prevent slippage.

The perpendicular extension 115, as shown in FIG. 4B, may comprise one or more spring structures 125. In an embodiment, the spring structures 125 create a spring-loaded connection with the metal connectors 120, allowing the attachment portion 100 to have a strong and adjustable attachment to a variety of structures.

FIG. 5 illustrates the present disclosure attached to a structure, such as a seat-back tray table 70. The rear support wall 105 and the front support wall 110 may be adjustably separated and clamped onto the seat-back tray table 70. The spring loaded connection between the metal connectors 120 and the spring structure(s) 125 allow the device mount 50 to adjust and conform to attach to a variety of surface widths. The slim nature of the rear support wall 105 and front support wall 110 allows the device mount 50 to attach to a diverse array of structures and may accommodate small or restrictive spaces, such as between a seat-back and tray table in the up/locked position. Furthermore, the perpendicular extension 115 creates an unobstructed ability for the device mount 50 to attach to any of various surfaces and prevent hindered or restricted adjustment of the rotation attachment 205 and device mounting portion 300, which can be selectively adjusted as described hereinbefore.

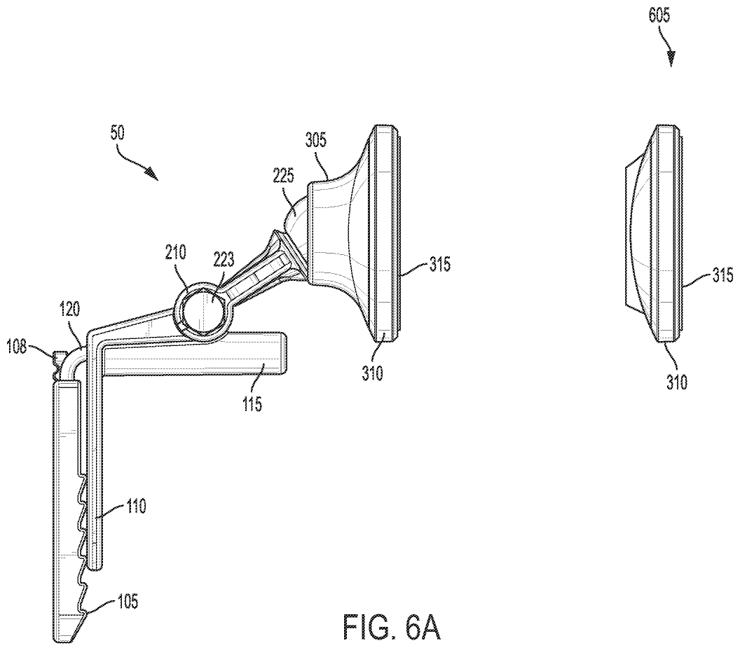

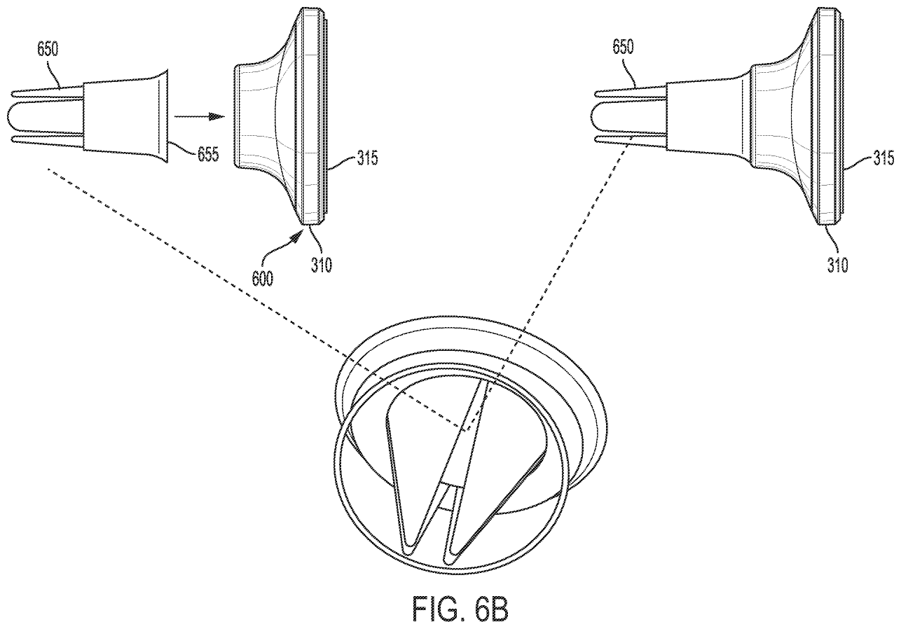

FIGS. 6A-6B illustrate a further embodiment of device mount apparatus 50. Mounting surface 310 in some cases may be configured as a removable mounting portion 600 and may, for example, be connected to an air-vent in a car via a universal air vent clip 650 (seen in FIG. 6B).

Referring specifically to FIG. 6A, removable mounting portion 600 interfaces with the device mounting portion 300 that has the ball-joint socket 305 that receives the ball-joint 225 of the angle adjustment unit 200. The removable mounting portion 600 may magnetically attach to mounting surface 310 (or other attachment interfaces are contemplated as mentioned above), allowing the removable mounting portion 600 to be easily detached from the mounting surface 310. The removable mounting portion 600 may be made of different materials, for example it may be metallic or include a magnet of opposite polarity to a magnetic surface included on the mounting surface 310. The removable mounting portion 600 may be removed and magnetically connected to a different device, for example a universal air vent clip 650 as shown in FIG. 6B.

FIG. 6B illustrates the removable mounting portion 600 attaching to the universal air vent clip 650. The universal air vent clip 650 may include a clip magnetic face 655. Mounting surface 310 of removable mounting portion 600 may magnetically attach to clip magnetic face 655 of universal air vent clip 650 to allow for simple and versatile attachment of a mobile device.

Furthermore, in addition to the features described and shown in the drawings, additional features or elements, for example features or elements commonly used in mobile device mounting or mounting devices, may be provided without departing from the scope of the present application.

While embodiments disclosed herein describe a mobile device mount that may be made or formed from various material, e.g. hardened nylons, plastic, PTFE, metals, or combinations thereof, one of ordinary skill in the art will appreciate that any number of materials, including, metal alloys, steel, stainless steel, or the like, may be used to form the components of the devices disclosed.

Further, while various components or pieces have been described herein as discrete components of the devices disclosed, one of ordinary skill in the art will appreciate that the devices may be formed or manufactured as a single piece or combined pieces, via mold, extrusion, three-dimensional printing, or the like, or may be formed from several pieces and connected, affixed, or attached by any number of known techniques.

Although the mounting device is described and shown having a ball-joint connection on the angle adjustment unit and having a ball-joint socket configured to receive the ball-joint connection on the mobile device mounting portion, it should be appreciated by those skilled in the art that such construction can be reversed such that the ball-joint socket is on the angle adjustment unit and the ball-joint connection configured to receive the ball-joint socket is on the mobile device mounting portion.

While embodiments disclosed herein describe a mobile device mount for use in clamping the mount to a structure such as an airplane or other vehicle seat back tray table, one of ordinary skill in the art will appreciate that the disclosure is not limited only to those exemplary uses and the devices described herein may be implemented in a variety of other areas and environments without deviating from the scope of the disclosure.

References to items in the singular should be understood to include items in the plural, and vice versa, unless explicitly stated otherwise or clear from the text. Grammatical conjunctions are intended to express any and all disjunctive and conjunctive combinations of conjoined clauses, sentences, words, and the like, unless otherwise stated or clear from the context. Thus, the term “or” should generally be understood to mean “and/or” and so forth.

Recitation of ranges of values herein are not intended to be limiting, referring instead individually to any and all values falling within the range, unless otherwise indicated herein, and each separate value within such a range is incorporated into the specification as if it were individually recited herein. The words “about,” “approximately,” “substantially,” or the like, when accompanying a numerical value or direction are to be construed as indicating a deviation as would be appreciated by one of ordinary skill in the art to operate satisfactorily for an intended purpose. Ranges of values and/or numeric values are provided herein as examples only, and do not constitute a limitation on the scope of the described embodiments. The use of any and all examples, or exemplary language (“e.g.,” “such as,” or the like) provided herein, is intended merely to better illuminate the embodiments and does not pose a limitation on the scope of the embodiments. No language in the specification should be construed as indicating any unclaimed element as essential to the practice of the embodiments.

In the description and following claims, it is understood that terms such as “first,” “second,” “third,” “above,” “below,” and the like, are words of convenience and are not to be construed as limiting terms unless expressly stated otherwise.

It will be appreciated that the devices and components described above are set forth by way of example and not of limitation. Numerous variations, additions, omissions, and other modifications will be apparent to one of ordinary skill in the art. In addition, any order or presentation of components or steps in the description and drawings above is not intended to require this order of performing any steps unless a particular order is expressly required or otherwise clear from the context. Thus, while particular embodiments have been shown and described, it will be apparent to those skilled in the art that various changes and modifications in form and details may be made therein without departing from the spirit and scope of this disclosure and are intended to form a part of the disclosure as defined by the following claims, which are to be interpreted in the broadest sense allowable by law.

What is claimed is:

1. A device mount apparatus for attaching mobile electrical devices to a structure, the device mount apparatus comprising:
an attachment portion including, a front support wall and a rear support wall extending co-axially along an axis, the front support wall having a perpendicular extension including a rotation attachment, wherein the rear support wall of the attachment portion is connected to the front support wall by a spring structure;
an angle adjustment unit, the angle adjustment unit having a mating portion configured to pivotably attach and rotate relative to the rotation attachment of the perpendicular extension of the front support wall, the angle adjustment unit having one of a ball-joint socket or a ball joint connection;
a mobile device mounting portion including, a mounting surface and one of a ball-joint socket or a ball joint connection configured to receive the one of the ball-joint socket or ball joint connection on the angle adjustment unit for connecting the angle adjustment unit to the mobile device mounting portion.

2. The device mount apparatus of claim 1, where the mounting surface of the mobile device mounting portion is magnetic.

3. The device mount apparatus of claim 1, where the rear support wall extends further than the front support wall.

4. The device mount apparatus of claim 1, where the surface of the rear support wall facing the front support wall is grooved.

5. The device mount apparatus of claim 1, where the rear support wall includes a tongue extension having a grooved surface on both sides.

6. The device mount apparatus of claim 1, where the angle adjustment unit is detachable from the perpendicular extension, by a pin having screw threads at one end.

7. The device mount apparatus of claim 1, where the rotation attachment of the angle adjustment unit includes a locking mechanism.

8. The device mount apparatus of claim 1, where the rear support wall is of a different width than the front support wall.

9. A device for attaching compact portable devices to a structure, the device comprising:
an attachment portion including, a front support wall and a rear support wall extending co-axially in the same direction along an axis, the front support wall having a perpendicular extension including a rotation attachment, wherein the rear support wall of the attachment portion is connected to the front support wall by a spring structure;
an angle adjustment unit, the angle adjustment unit having a T hinge mating portion configured to attach and pivotably rotate relative to the rotation attachment of the perpendicular extension of the front support wall, the angle adjustment unit having a ball-joint connection;
a compact portable device mounting portion including, a mounting surface and a ball-joint socket configured to receive the ball-joint connection for connecting the angle adjustment unit to the compact portable device mounting portion, wherein the connection is configured to allow the compact portable device mounting portion to swivel 360 degrees and tilt to a selected viewing angle.

10. The device of claim 9, where the mounting surface of the compact portable device mounting portion is magnetic.

11. The device mount apparatus of claim 9, where the rear support wall extends further than the front support wall.

12. The device mount apparatus of claim 9, where the surface of the rear support wall facing the front support wall is grooved.

13. The device mount apparatus of claim 9, where the rear support wall includes a tongue extension having a grooved surface on both sides.

14. The device mount apparatus of claim 9, where the angle adjustment unit is detachable from the perpendicular extension, by a pin having screw threads at one end.

15. The device mount apparatus of claim 9, where the rotation attachment of the angle adjustment unit includes a locking mechanism.

16. A method of configuring a device for attaching compact portable devices to a structure, the method comprising:
providing an attachment portion formed to include, a front support wall and a rear support wall, the front support wall having a perpendicular extension including a rotation attachment, wherein the rear support wall of the attachment portion is connected to the front support wall by a spring structure;
providing an angle adjustment unit, formed having a T hinge mating portion configured to attach and pivotably rotate relative to the rotation attachment of the perpendicular extension of the front support wall, the angle adjustment unit formed having a ball-joint connection;
providing a compact portable device mounting portion including, a mounting surface and a ball-joint socket configured to receive the ball-joint connection for connecting the angle adjustment unit to the compact portable device mounting portion, wherein the connection is configured to allow the compact portable device mounting portion to swivel 360 degrees and tilt to a selected viewing angle.
